(19) United States
(12) Patent Application Publication
(10) Pub. No.: US 2026/0341391 A1
(43) Pub. Date: Oct. 29, 2026

(54) MEMORY DEVICE AND METHOD OF DETERMINING AN INTEGRITY STATE OF A MEMORY DEVICE

(71) Applicant: Infineon Technologies AG, Neubiberg (DE)

(72) Inventors: Thomas Kern, Aschheim (DE); Akshaya Prashanthi Lakshmi Narayanan, Kancheepuram (IN); Matteo Coppetta, Padova (IT); Sebastian Kiesel, München (DE); Thomas Rabenalt, Unterhaching (DE)

(21) Appl. No.: 19/578,972

(22) Filed: Mar. 26, 2026

(30) Foreign Application Priority Data
Apr. 24, 2025 (DE) 10 2025 115 892.4

(51) Int. Cl. G11C 29/52; G11C 16/26; G11C 16/34

(52) U.S. Cl. CPC G11C 29/52; G11C 16/26; G11C 16/349

(57) ABSTRACT

A method of determining an integrity state of a memory device is provided. The memory device includes a plurality of memory elements, including a first set of memory elements defined by a first bit value and a second set of memory elements defined by a second bit value. The method includes reading the first set of memory elements applying a first offset current and comparing a sum formed by a current through the memory element and the first offset current with a first predefined reference current and with a second predefined reference current or reading the second set of memory elements applying a second offset current and comparing a sum formed by a current through the memory element and the second offset current with the first and the second predefined reference current, determining the integrity state of the plurality of memory elements using the results of the reading.

### REFERENCE TO RELATED APPLICATION

This Application claims the benefit of German Application number 10 2025 115 892.4, filed on Apr. 24, 2025, the contents of which are hereby incorporated by reference in their entirety.

### TECHNICAL FIELD

Various embodiments relate generally to a method of determining an integrity state of a memory device and to a memory device.

### BACKGROUND

Memory devices, more specifically, resistive non-volatile memory devices (also referred to as resistive NVMs) may experience degradation over time.

The top panel of FIG. 1A illustrates a distribution 100 of resistive states of a plurality of resistive memory elements as measured in a prior art memory device. When reading the memory elements using a single reference current IREF (such a read process is also referred to as “single ended read”), at the beginning of life of the memory device, two distributions of resistive states are clearly separated, namely a high resistive state (HRS) and a low resistive state (LRS).

The bottom panel of FIG. 1A illustrates a distribution 101 towards the end of life of the memory device. The respective distributions of the HRS memory elements and the LRS memory elements have not only broadened to fill the gap between them, but also respectively “spilled over the reference current IREF” and overlap each other.

This means that some of the HRS memory elements will be falsely identified as LRS memory elements, and vice versa.

Such read results and the respective assigned bit values may be referred to as “corrupted” or “corrupt”. Up to a certain limit, corrupted bits may be corrected using an error correction code (ECC).

However, at some point, a correction capability of an ECC may be exhausted, and a state may be reached in which the memory device may be unusable. Saftety relevant applications, specifically, may call for a warning ahead of failure to allow for timely replacement of the memory device.

FIG. 1B schematically illustrates, for the distributions 100, 101 of FIG. 1A, an integrity test of the memory device, also referred to as a robustness test, in accordance with a prior art.

As an illustrative way to describe it, the reference current IREF may be shifted towards each of the distributions (HRS/LRS), i. e., to a higher current and to lower current, respectively (indicated by the dashed lines and the ±AI. Such a process may also be referred to as tight margin read in standard single ended.

As can be seen from a comparison of the top panel and the bottom panel, near the start of life, there may be none or only few corrupted bits (and thus errors that require correction). Margin reads using the ±AI offset reference currents may be used for checking a distance to the respective main LRS/HRS distributions by registering the ECC errors. However, the number of errors may increase as the device ages. A number of ECC errors at the nominal reference current and at the ±AI offset reference currents may be registered.

### SUMMARY

A method of determining an integrity state of a memory device is provided.

The memory device includes a plurality of memory elements, including a first set of memory elements defined by a first bit value and a second set of memory elements defined by a second bit value. The method includes carrying out a margin read, including: reading the first set of memory elements applying a first offset current and comparing a sum formed by a current through the memory element and the first offset current with a first predefined reference current and with a second predefined reference current and/or reading the second set of memory elements applying a second offset current and comparing a sum formed by a current through the memory element and the second offset current with the first predefined reference current and with the second predefined reference current, determining the integrity state of the plurality of memory elements using the results of the reading the first set of memory elements and/or the second set of memory elements.

A memory device is provided. The memory device includes a plurality of memory elements, including: a first set of memory elements defined by a first bit value, and a second set of memory elements defined by a second bit value, at least one detector electrically conductively connectable to the plurality of memory elements, an offset current source/drain electrically conductively connectable to the at least one detector, and a processor, wherein the memory device is configured to carry out a margin read, including: reading the first set of memory elements applying a first offset current and comparing a sum formed by a current through the memory element and the first offset current with a first predefined reference current and with a second predefined reference current and/or reading the second set of memory elements applying a second offset current and comparing a sum formed by a current through the memory element and the second offset current with the first predefined reference current and with the second predefined reference current, determining the integrity state of the plurality of memory elements using the results of the reading the first set of memory elements and/or the second set of memory elements.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A illustrates distributions of resistive states of a plurality of resistive memory elements as measured in a prior art memory device;

FIG. 1B schematically illustrates an integrity test of the prior art memory device;

FIG. 2A illustrates distributions of resistive states of a plurality of resistive memory elements as measured in a memory device in accordance with various embodiments;

FIG. 2B illustrates an effect of applying a robustness test method of FIG. 1B to the memory device of FIG. 2A;

FIG. 2C schematically illustrates an integrity test of a memory device in accordance with various embodiments;

FIG. 3A schematically illustrates a memory device in accordance with various embodiments;

each of FIGS. 3B and 3C schematically illustrates an integrity test of a memory device in accordance with various embodiments;

FIG. 4A schematically illustrates reading a memory device in accordance with various embodiments and an error correction of the read data;

FIG. 4B schematically illustrates an integrity test of the memory device of FIG. 4A in accordance with various embodiments;

FIG. 5 shows a flow diagram of a method of testing a memory device in accordance with various embodiments; and

FIG. 6 shows a flow diagram of a method of testing a memory device in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In the following, embodiments are described with reference to resistive memory devices like Resistive Random Access Memories (RRAM) and the like. It is, however, to be understood that methods and memory devices may, mutatis mutandis, also be applied to charge trapping memory devices, for example floating gate flash memory devices and charge trap flash memory devices and methods for testing their integrity state. As an example for adjustments that may be applied to the method when charge trapping memory elements are used instead of resistive memory elements may be that respective bit values of the memory elements may be determined by an amount of charge trapped in the memory element, rather than through a resistive state of the memory element.

Thus, the memory elements described herein may include or consist of resistive memory elements (memristive elements) and/or charge-trapping memory elements.

A method of determining an integrity state of such a memory device and a memory device configured to determine its integrity state are provided in various embodiments.

In various embodiments, an integrity test is provided for a multi-reference read (also referred to as Single Ended Smart, SES). Illustratively, a shift in a first direction (e. g., a down shift) of a low resistance state (LRS) distribution and a shift in a second direction (e. g., an opposite direction, e. g., an upshift) of a high resistance state (HRS) distribution is performed.

In various embodiments, an ECC engine may be provided and applied to bits resulting from a read process (e. g., an initial read process) to identify an origin of data bits to apply the correct margin currents (in other words, to determine for each individual memory cell whether to apply a shift in the first direction or in a second direction). This may particularly apply to memory devices in the field, which may be written with arbitrary unknown data. In an embodiment where known data, e. g., test data like a checkerboard pattern or the like, or for example data that are used in the field where it is known which bit values are stored in the memory cells, the initial read process may be omitted.

Without being limited thereto, the HRS may usually be identified as a “0” bit value, and the LRS may usually be identified as a “1” bit value. Examples herein may make use of this identification, with the understanding that, generally, a different identification may be used, for example identifying HRS as “1” and LRS as “0”.

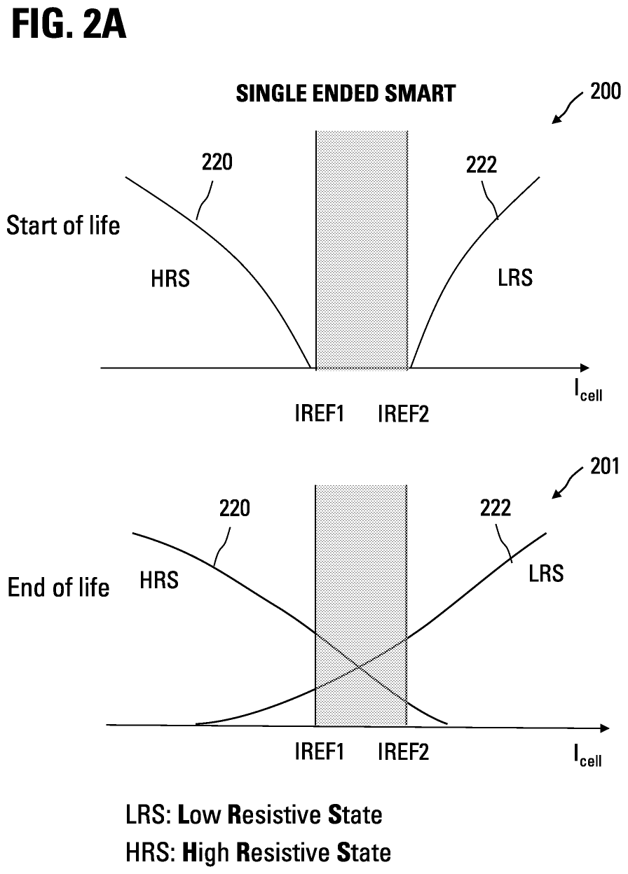

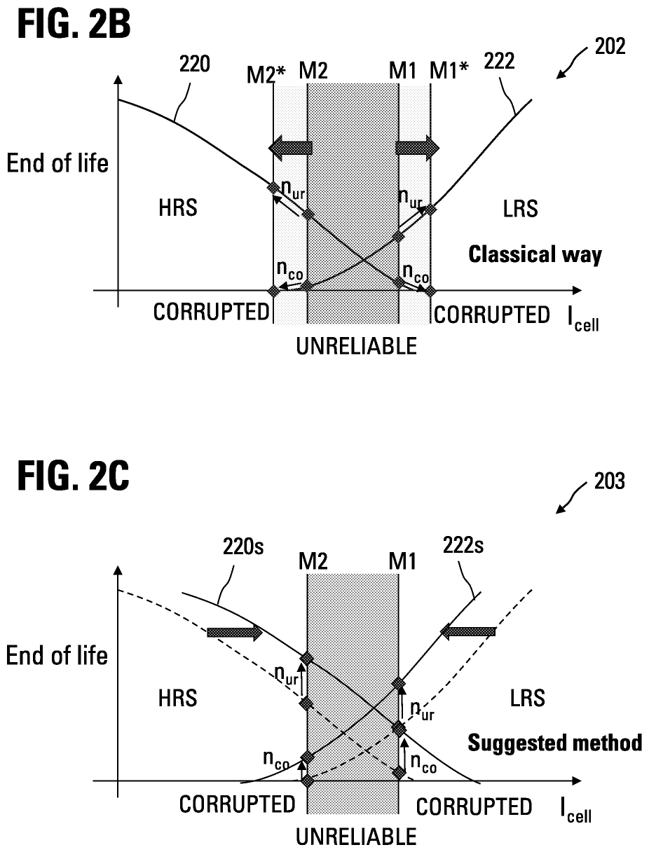

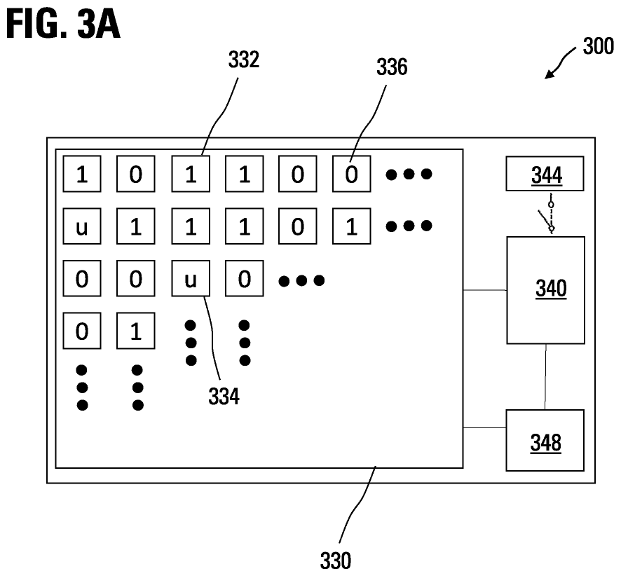

FIG. 2A illustrates distributions 200, 201 of resistive states of a plurality of resistive memory elements as measured in a memory device in accordance with various embodiments.

The top panel illustrates the distribution 200 at a start of life of the memory device. The memory device in accordance with various embodiments may be configured for a read method that uses a multi-level read scheme, also referred to as single ended smart (SES). Here, two read levels, IREF1 and IREF2, may be used, which may be considered to form margins of a range between the margins.

As can be seen from the distribution 200 shown in the top panel of FIG. 2A, at the beginning of life, the LRS and the HRS distributions may be cleanly separated by both reference currents IREF1 and IREF2, with the LRS distribution being fully located at cell currents above both reference currents IREF1, IREF2, and the HRS distribution being fully located at cell currents below both reference currents IREF1, IREF2, such that no (or almost no) cell currents are identified in the memory device that lie between the two reference currents IREF1, IREF2.

Near the end of life, as illustrated by the distribution 201 in the bottom panel, each of the distributions HRS, LRS may have broadened and/or shifted to cross both reference currents IREF1, IREF2, which means that an initial read process may include correctly identified HRS bits, correctly identified LRS bits, incorrectly identified (corrupted) HRS bits, incorrectly identified (corrupted) LRS bits, and bits located between both reference currents IREF1, IREF2 (the area is highlighted by a grey box in FIG. 2A). Resistance states of memory elements that end up in the grey area between the two reference currents IREF1, IREF2 may be determined to be HRS bits when the second reference current IREF2 is considered in the read process, and be determined to be LRS bits when the first reference current IREF1 is considered in the read process. This means that bits in the grey area are unreliable bits. Both, unreliable bits and corrupted bits, may be correctable/corrected by an ECC to some extent.

However, also for the SES read method, an ECC correction capacity may be exhausted at some point, and an integrity test of the memory device may be desired.

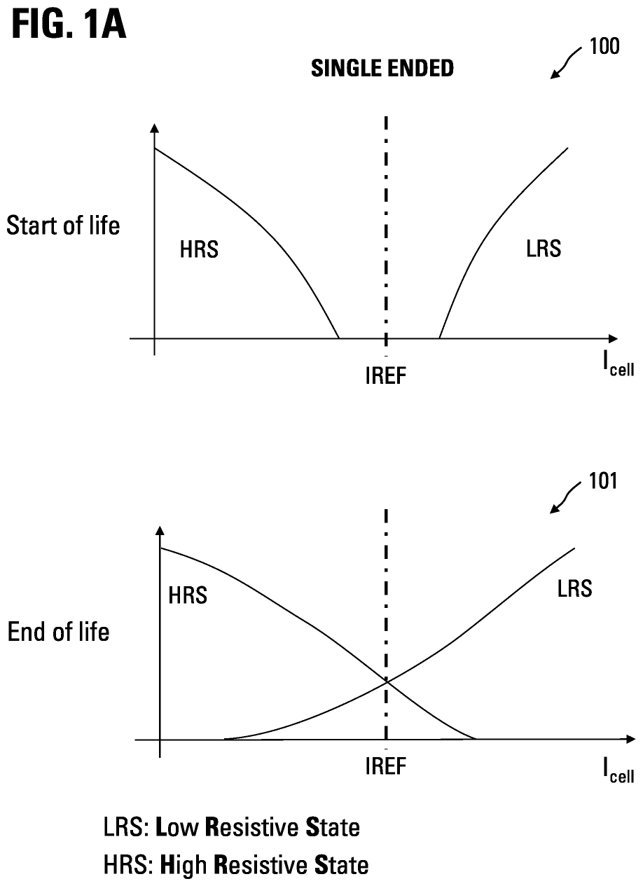

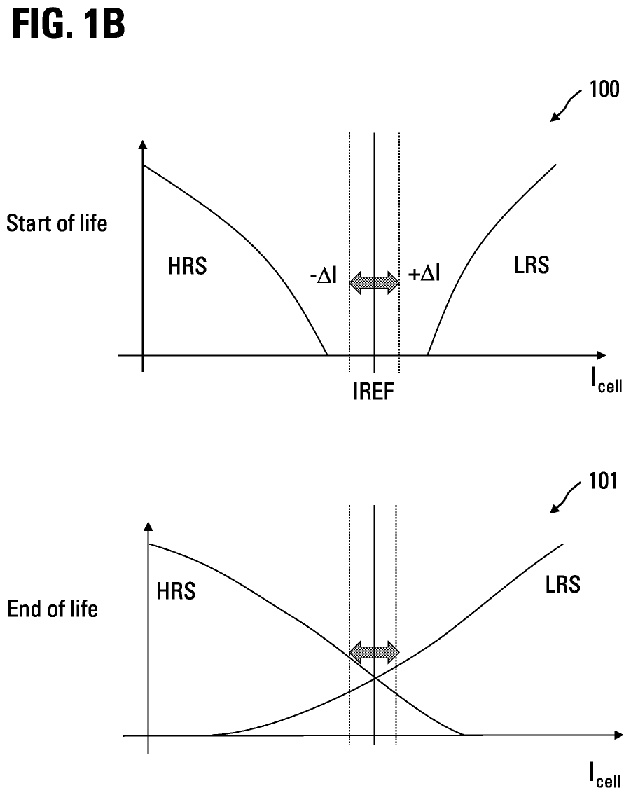

FIG. 2B illustrates an effect of applying an integrity test method based on a similar principle as the prior art method of FIG. 1B to the memory device of FIG. 2A, more specifically to a memory device configured for the SES read method using two reference cell currents. The two reference cell current values are labelled M1 and M2, respectively, for first margin M1 and second margin M2. It is to be understood that “first”, “second”, “1”, “2”, in this case, are not meant to indicate an order or a priority, but merely to differentiate the two reference values representing the margins and are in principle interchangeable.

The “similar principle” may involve artificially simulating that the HRS and LRS distributions, respectively, come closer to both margins M1, M2.

FIG. 2B illustrates, in distribution 202, what happens if the area between the margins M1, M2 is broadened by shifting the first margin M1 outward to the shifted margin M1* and shifting the second margin M2 outward to M2*.

However, such a measure would not necessarily, as intended, worsen the situation (like a case of a higher lifetime would), because the number of corrupted bits n_{cor} is actually decreased, rather than increased, and the number of bits in the unreliable range nᵤᵣ may be increased, but probably not into the uncorrectable range. See the arrows in FIG. 2B indicating how n_{co} and nᵤᵣ evolve with an increasing distance between the margins M1, M2 (or M1*, M2*, respectively).

In various embodiments, rather than increasing a distance between the margins M1, M2, (which would move one of the margins M1, M2 towards, for example, the HRS distribution, but the other of the margins M2, M1 away from the HRS distribution, as shown in FIG. 2B), a distance between the margins M1, M2 may be kept the same, but a differential shifting of both, the HRS distribution and/or the LRS distribution with respect to the margins M1, M2 may be applied.

FIG. 2C schematically illustrates, in a distribution 203, an integrity test of a memory device in accordance with various embodiments.

The above described differential shifting is illustrated as a shift of the HRS distribution (the HRS distribution may be considered as representing a first set of memory elements defined by a first bit value, e. g., a bit value of “0”) and the LRS distribution (the LRS distribution may be considered as representing a second set of memory elements defined by a second bit value, e. g., a bit value of “1”), respectively, towards the margins M1, M2.

As can be seen from FIG. 2C, e. g., from the arrows visualizing how the shift affects the unreliable bits nᵤᵣ and the corrupted bits n_{cor}, such a shift leads to an increase of both, the unreliable bits nᵤᵣ and the corrupted bits n_{cor}. This means that the suggested method is suitable for simulating an aging effect on the memory device.

As a consequence, a differential shifting of the HRS distribution (e. g., the first set) into a first direction and of the LRS distribution (e. g., the second set) into a different, second direction may be used, for example repeatedly over time, to estimate when a point may be reached at which the memory device may include too many errors to allow for a correction for all of them. Optionally, a corresponding warning may be issued, such that the memory device may be replaced.

To put it differently, for simulating a real closure (moving towards each other) of the HRS and the LRS distributions with age, a tight margin read may be applied using a current adder on the memory elements corresponding to the HRS distribution (which may typically be considered to represent a “0” bit value), and a current drain, lowering or subtraction, on the memory elements corresponding to the LRS distribution (which may typically be considered to represent a “1” bit value). In this way, the reference currents may remain fixed.

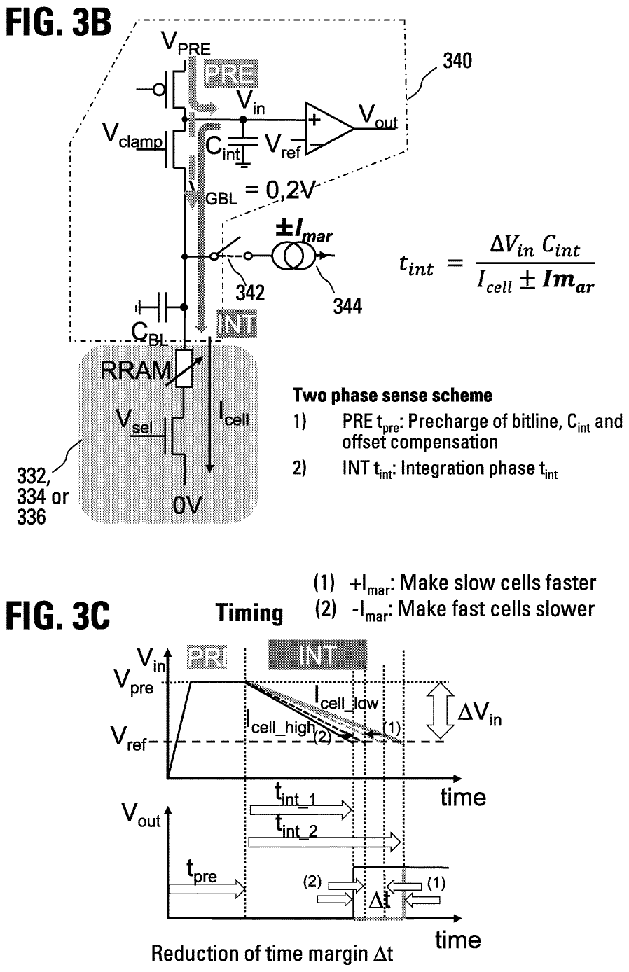

FIG. 3A illustrates a memory device 300 in accordance with various embodiments, including a plurality of resistive memory elements 330, e. g., an array of resistive memory elements 330, and a read circuit 340, e. g., a sense amplifier, configured to determine a resistive state of each of the resistive memory elements 330 via a read process. The read circuit 340 may be configured to be used for determining the resistive state of the memory element 330 being read using two reference values, e.g., reference currents, as described above, or for example reference times, for example as described in context with FIG. 3B and with FIG. 3C, or for example reference voltages (not shown in the figures).

As described above, the plurality of resistive memory elements 330 (also referred to as memory elements or elements, for short) may include resistive memory elements 336 in a high resistive state HRS, which may usually be identified with a “0” bit value, memory elements 332 in a low resistive state LRS (usually identified with a “1” bit value), and memory elements 334 in an unreliable state u as described above.

FIGS. 3B and 3C jointly schematically illustrate a method of determining an integrity state (e. g., an integrity test, also referred to as a robustness test) of a memory device in accordance with various embodiments, for example of the memory device 300 of FIG. 3A. They specifically illustrate how the read circuit 340 may be configured in a specific exemplary embodiment, to realize the differential shifting of the HRS and the LRS distributions, i. e., the shifting depending on their resistive state.

In the specific exemplary embodiment, a read circuit 340 that determines a time for discharging a pre-charged capacitor Cint across the memory element 332, 334 or 336 as compared with a reference time, may be used for determining the resistive state of the memory element 332, 334 or 336. It is to be understood that other concepts for determining the resistive state (e. g., current-based, voltage-based) may be used instead or in addition.

As indicated in FIG. 3B, the capacitor Cᵢₙₜ (and a bitline) may be pre-charged during a pre-charge phase of duration tₚᵣₑ using a precharge voltage V_{PRE} as part of the read process (see the arrows and phase labelled “PRE” in FIGS. 3B and 3C, respectively). During the precharge time an offset compensation to the comprator may be applied. The read process itself (also referred to as integration phase of duration tint) may involve switching a selection transistor of the memory element 332, 334, or 336, causing the discharge of the capacitor Cᵢₙₜ (see the arrow and phase labelled “INT” in FIGS. 3B and 3C, respectively).

As indicated in FIG. 3B, the duration of the integration phase tint may be determined by:

$${t}_{int} = \frac{Δ {V}_{in} {c}_{int}}{{I}_{cell} \pm {I}_{mar}}$$

As an illustrative way to describe the read process of FIGS. 3B and 3C to the reference currents IREF1, IREF2 described above, for the single ended smart read method, the two reference currents IREF1 and IREF2 may be compared to the cell current Icell.

In the case where the offset current Iₘₐᵣ is provided, the sum of the cell current Icell and the (positive or negative) offset current is compared to each of the reference currents IREF1, IREF2, for example by comparing the respective integration phase tint. An exemplary embodiment of such a read method is illustrated in FIG. 3C.

The shifts (also referred to as offsets) may be applied to the cell current Icell before being compared to each of the two reference currents IREF1 and IREF2. For example, when reading a memory element 336 in the high resistive state HRS (“slow cells”, e. g., being assigned a bit value of “0”), the additional (positive) offset current +Iₘₐᵣ may make them faster. When reading a memory element 332 in the low resistive state LRS (“fast cells”, e. g., being assigned a bit value of “1”), the current diminished by the (negative) offset current −Iₘₐᵣ may make them slower.

In a usual read process, e. g., a read process that uses a common reference time/current/voltage without a shift/an offset Iₘₐᵣ, a switch 342 may be open.

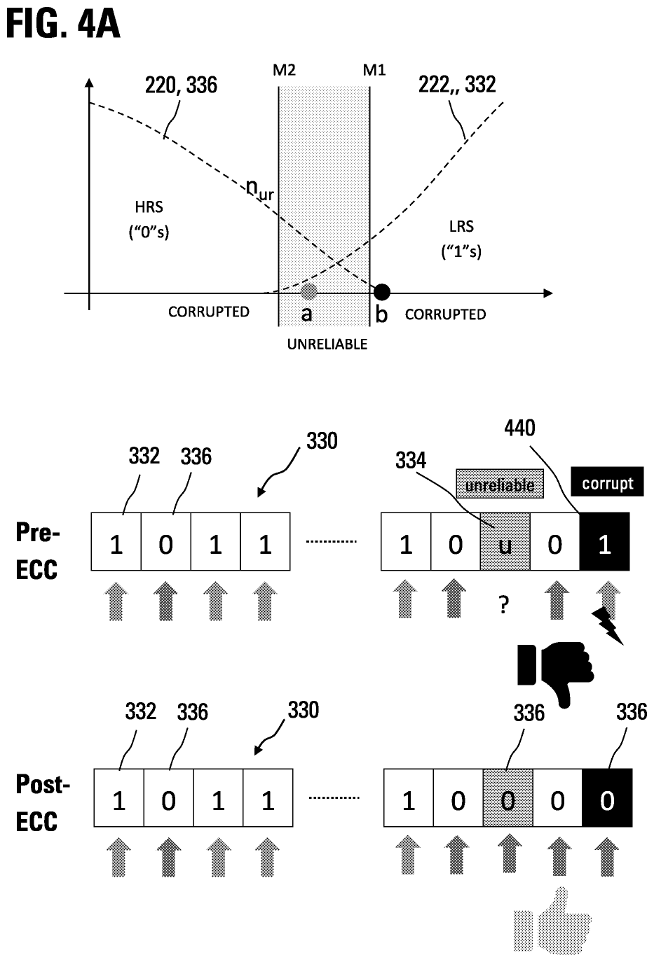

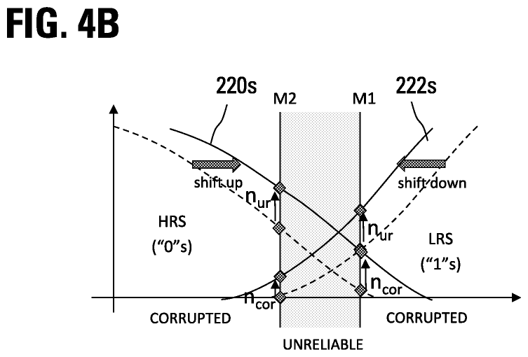

For applying an additional current (adding or subtracting a margin shift current Iₘₐᵣ), the switch 342 may be closed, thereby connecting the read circuit 340 to a current source or drain (commonly referred to as current source/drain 344, wherein it is to be understood that, during a single read process, the current source/drain either acts as a current source by providing +Iₘₐᵣ or as a current drain by providing the (subtractive) current −Iₘₐᵣ) for providing the margin shift current Iₘₐᵣ. The switch 342, e. g., configured as another transistor or transmission gate, may be activated for a read process with a shifted margin, e. g., as described in context with FIG. 2C and FIG. 4B (which is similar to FIG. 2C, but additionally indicates the typical bit values assigned to HRS and LRS, respectively) for shifting a current seen by the sense amplifier when reading the memory elements of the HRS distribution (e. g., the “0”-bit-memory elements 336) towards higher currents (towards the LRS distribution and thus to the right/up in FIG. 2C and FIG. 4B) or for shifting a current seen by the sense amplifier when reading the memory elements of the LRS distribution (e. g., the “1”-bit-memory elements 332) towards lower currents (towards the HRS distribution and thus to the left/down in FIG. 2C and FIG. 4B).

As indicated in FIG. 3C for the time-based read method, adding the margin shift current (+Iₘₐᵣ) may make slow (HRS) cells faster (indicated by (1) in FIG. 3C), and subtracting the margin shift current (−Iₘₐᵣ) may make fast (LRS) cells slower (indicated by (2) in FIG. 3C), thereby diminishing a time difference for the two resistive states, indicated by the shifting of the dashed vertical lines, and thereby simulating a degradation of the memory device 300.

As an alternative, a shifting in the opposite direction, i. e., a simulated improvement of the memory device 300, may be applied, for example for determining by how far the HRS and the LRS distributions need to be shifted away from each other in order to obtain a zero-error-state. Analyzing/Monitoring such a value over time may document that larger and larger shifts may be required for obtaining an error-free read, and may make a warning ahead of a memory device failure equally possible as the simulated degradation described before.

As described above, a direction of a shift/offset during a read process applied as part of the integrity test of various embodiments depends on a resistance state of the memory element 330 that is read.

However, with a degradation of the memory device 300 and as illustrated in FIG. 4A, more and more memory elements 330 may be located in the unreliable region (indicated by the dot labelled a) or may even be corrupt (indicated by a dot labelled b).

Thus, in order to be able to select the correct shift/offset, they may need to be assigned their correct resistance state, in other words, whether they originated from the LRS distribution 222, or from the HRS distribution 220.

An error correction code ECC may be used for this purpose. It is to be understood that, at least in some cases, an error detection may be used before the correction, using a respective error detection code EDC.

The middle panel of FIG. 4A illustrates a sequence of memory elements with their assigned bit values corresponding to the resistance states that result from an initial read process. As indicated, the sequence of memory elements includes an unreliable and a corrupt bit.

The bottom panel of FIG. 4A illustrates the bit values after an application of the ECC. Both, the unreliable bit and the corrupt bit have been corrected.

A burden on the EDC/ECC originating from the unreliable bits 334 may be lighter than the burden from the corrupt bits 440, since the unreliable bits 334 are already identified via the single ended smart read process.

As long as the ECC is able to correct all errors, the integrity test may be executed. Otherwise, an error may be issued.

More generally, the memory device 300 and its configuration for determining its integrity state in accordance with various embodiments may be described as follows:

The memory device 300 includes a plurality of memory elements 330 including: a first set of memory elements 336 defined by a first bit value (without limiting thereto, in FIG. 4A, the exemplary first bit value is the value “0” of the HRS distribution 220), and a second set of memory elements 332 defined by a second bit value (without limiting thereto, in FIG. 4A, the exemplary second bit value is the value “1” of the LRS distribution 222), at least one read circuit 340 electrically conductively connectable to the plurality of memory elements 330, an offset current source/drain 344 electrically conductively connectable to the at least one read circuit 340, and a processor 348, wherein the memory device 300 is configured to carry out a margin read, including: reading the first set 336 of memory elements applying a first offset current and comparing a sum formed by a current through the memory element and the first offset current with a first predefined reference current IREF1 and with a second predefined reference current IREF2 and/or reading the second set of memory elements 332 applying a second offset current and comparing a sum formed by a current through the memory element and the second offset current with the first predefined reference current IREF1 and with the second predefined reference current IREF2, determining the integrity state of the plurality of memory elements using the results of the reading the first set 336 of memory elements and/or the second set 332 of memory elements.

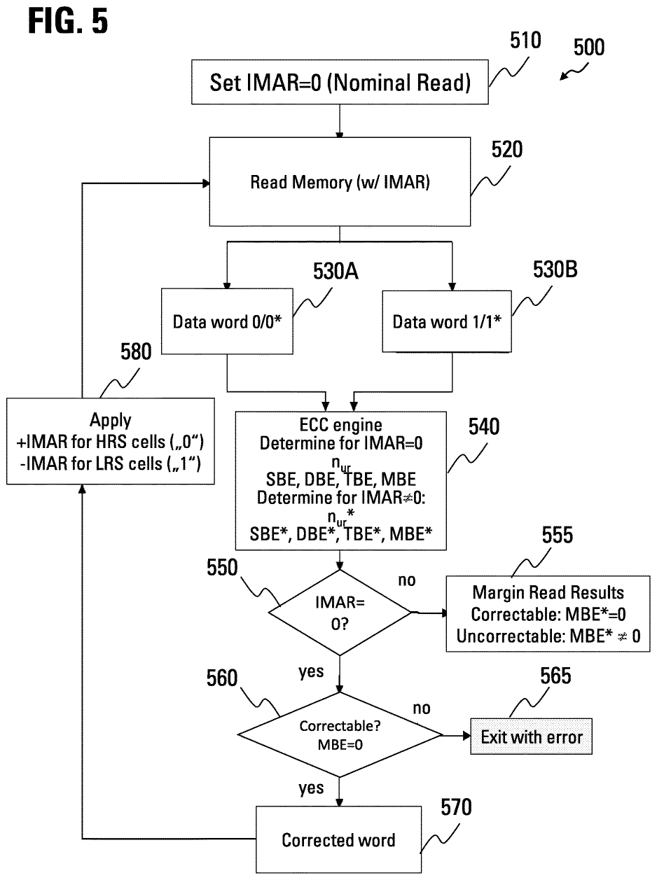

FIG. 5 shows a flow diagram 500 of a method of determining an integrity state of a memory device in accordance with various embodiments.

The method includes setting I_{MAR} to zero (at 510; this corresponds to a nominal read process, in this case for the single ended smart read process using two reference currents IREF1, IREF2).

Subsequently, the memory may be read with IMAR (of zero) (at 520). Due to the two reference currents, this may lead to two data words 0 (at 530A) and 1 (at 530B), respectively.

Subsequently, an ECC engine may be applied to the data words for correcting them. Various numbers may be registered, for example the number or unreliable bits nur, the number of single bit errors SBE, double bit errors DBE, triple bit errors TBE, and multi bit errors MBE (in 540).

At 550, it is determined whether IMAR is zero. Since this is the case (yes-path), it is determined (at 560) whether the bits are correctable, which is the case if the number of multi-bit-errors is zero. If this is not the case, the method is aborted with an error (at 565).

If the word is correctable, the corrected word is provided (at 570) and the shift/offset is provided: +IMAR for the HRS cells (those with a bit value of “0”) and −IMAR for the LRS cells (those with a bit value of “1”), and the method may continue at 520 with the reading of the memory, this time with an IMAR different from zero.

This means that respective data words 0*, 1* resulting (in 530A and 530B, respecively) from the read process may differ from the data words 0, 1 that had resulted from the nominal read with IMAR=0.

Again, at 540, the ECC engine may be applied, and a number of unreliable bits nᵤᵣ*, of single bit errors SBE*, double bit errors DBE*, triple bit errors TPE*, and multi bit errors MBE* may be determined. In various embodiments, for simply determining the type of error that is present, applying an error detection code (e. g., without actually correcting any of the errors) may be sufficient.

At 550, it will be determined that IMAR is different from zero, thus the “no” path will be followed and an analysis of the ECC results may be provided at 555. For example, it may determined (and optionally reported, in particular in a case of uncorrectable multi bit errors MBE*, but possibly also in a case that no multi bit errors are found (MBE*=0)).

The method in accordance with various embodiments illustrated in FIG. 5 may exit with success at 555 after a single run with the shift values +IMAR and −IMAR, respectively. In various embodiments, the method may include applying several different shift/offset values for IMAR. For example, increasing or decreasing values may be applied.

In various embodiments, the plurality of memory elements 330 subjected to the integrity test may have a statistically significant number, for example the whole memory device 300. However, in various embodiments, a subset of the memory elements 330 may be sufficiently significant, for example a half, quarter, etc., of the plurality of memory elements 330 included in the memory device 300.

In that case, it may be possible to run the integrity test separately for sub-sections of the memory device 300. If an extent of degradation is more severe in some of the subsets than in others, a use scheme may optionally be adapted. For example, the memory elements 330 in the less degraded subset(s) may be used more intensely in the future, while those in the more severely degraded subset(s) may be spared.

As outlined above, the integrity test in accordance with the method of various embodiments may be suitable for being executed in the field, when the memory elements 330 have real data values stored in them. The method may for example be executed upon startup, during idle times, during other suitable times, and/or upon request.

In various embodiments, the integrity test may, for example additionally, be executed after production, before the memory device 300 is shipped to the customer, for example for quality control and/or for providing a reference base for future measurements. In that case, the memory device 300 may not have any real data stored yet, and a known test pattern may be written. In that case, the nominal read process without the shift/offset IMAR for determining an origin of the resistance state of the memory cell may be omitted, since the resistive state of the memory element 330 is defined through the write process, and thus it is known which direction of the offset (+IMAR or −IMAR) is to be applied to each of the memory elements 330.

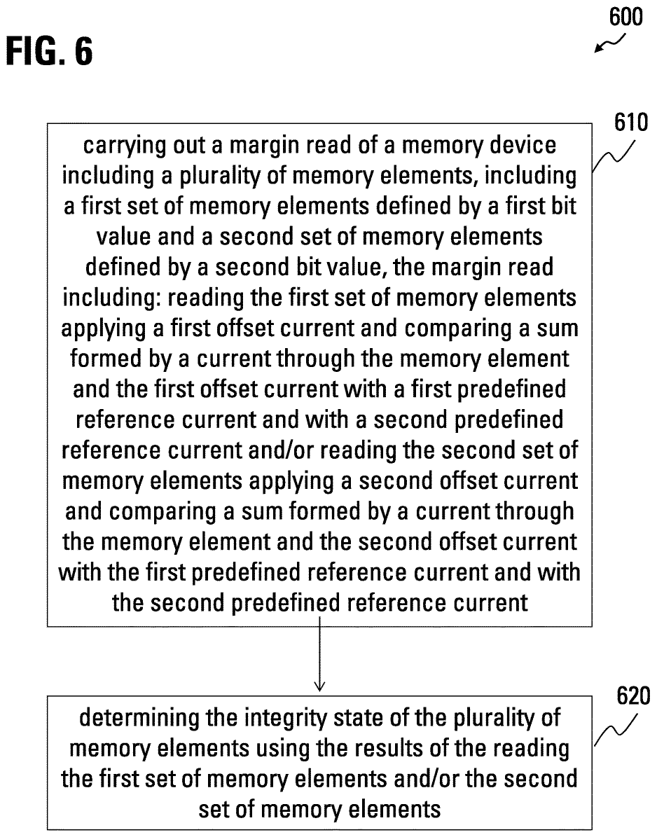

FIG. 6 shows a flow diagram 600 of a method of testing a memory device in accordance with various embodiments.

The method includes carrying out a margin read of a memory device including a plurality of memory elements, including a first set of memory elements defined by a first bit value and a second set of memory elements defined by a second bit value, the margin read including: reading the first set of memory elements applying a first offset current and comparing a sum formed by a current through the memory element and the first offset current with a first predefined reference current and with a second predefined reference current and/or reading the second set of memory elements applying a second offset current and comparing a sum formed by a current through the memory element and the second offset current with the first predefined reference current and with the second predefined reference current (in 610) and determining the integrity state of the plurality of memory elements using the results of the reading the first set of memory elements and/or the second set of memory elements (in 620).

Various examples will be illustrated in the following:

Example 1 is a method of determining an integrity state of a memory device, the memory device including a plurality of memory elements, including a first set of memory elements defined by a first bit value and a second set of memory elements defined by a second bit value, the method including: carrying out a margin read, including: reading the first set of memory elements applying a first offset current and comparing a sum formed by a current through the memory element and the first offset current with a first predefined reference current and with a second predefined reference current and/or reading the second set of memory elements applying a second offset current and comparing a sum formed by a current through the memory element and the second offset current with the first predefined reference current and with the second predefined reference current, determining the integrity state of the plurality of memory elements using the results of the reading the first set of memory elements and/or the second set of memory elements.

In Example 2, the subject-matter of Example 1 may optionally further include carrying out an initial read process, including: defining the memory elements for which a current through the cell during the read is lower than the first predefined reference current and lower than the second predefined reference current as belonging to the first set, defining the memory elements for which the current through the cell during the read is higher than the first predefined reference current and higher than the second predefined reference current as belonging to the second set, and defining the memory elements for which the current through the cell during the read is higher than the first predefined reference current and lower than the second predefined reference current as being in an unreliable state, applying an initial error correction to a result of the initial read process, and defining the memory elements that, after the initial error correction, are assigned the first bit value, as belonging to the first set, and defining the memory elements that, after the initial error correction, are assigned the second bit value, as belonging to the second set.

In Example 3, the subject-matter of Example 1 may optionally include that the defining the first set and the second set includes providing a predefined memory state pattern including first bit values that define the first set, and second bit values that define the second set.

In Example 4, the subject-matter of any of Examples 1 to 3 may optionally include that an offset direction of the second offset current is opposite to an offset direction of the first offset current.

In Example 5, the subject-matter of any of Examples 1 to 4 may optionally further include providing the first offset current with a first direction and the second offset current with a second direction, wherein the sum formed by a current through the memory element and the first offset current is higher than the current through the memory element, and wherein the sum formed by a current through the memory element and the second offset current is lower than the current through the memory element, or that the sum formed by a current through the memory element and the first offset current is lower than the current through the memory element, and wherein the sum formed by a current through the memory element and the second offset current is higher than the current through the memory element.

In Example 6, the subject-matter of any of Examples 1 to 5 may optionally include that, for each memory element of the first set, a result of the comparing the sum formed by the current through the memory element and the first offset current with the first predefined reference current is a first read result, a result of the comparing the sum formed by the current through the memory element and the first offset current with the second predefined reference current is a second read result, the determining the integrity state including: classifying each of the memory elements of the first set into one of a plurality of correctability states, the classifying including: assigning a valid state to each memory element of the first set where the first read result and the second read result have the first bit value, assigning an unreliable state to each memory element of the first set where only one of the first read result and the second read result has the first bit value, and assigning a corrupt state to each memory element of the first set where none of the first read result and the second read result have the first bit value.

In Example 7, the subject-matter of any of Examples 1 to 6 may optionally include that, for each memory element of the second set, a result of the comparing the sum formed by the current through the memory element and the second offset current with the first predefined reference current is a third read result, a result of the comparing the sum formed by the current through the memory element and the second offset current with the second predefined reference current is a fourth read result, the determining the integrity state including: classifying each of the memory elements of the second set into one of a plurality of correctability states, the classifying including: assigning a valid state to each memory element of the second set where the third read result and the fourth read result have the second bit value, assigning an unreliable state to each memory element of the second set where only one of the third read result and the fourth read result has the second bit value, and assigning a corrupt state to each memory element of the second set where none of the third read result and the fourth read result have the second bit value.

In Example 8, the subject-matter of any of Examples 1 to 7 may optionally include that the carrying out the margin read includes the reading the first set of memory elements and the reading the second set of memory elements, and that the determining the integrity state of the plurality of memory elements includes applying an error detection code, EDC, and/or an error correction code, ECC, using the results of the reading the first set of memory elements and the second set of memory elements.

In Example 9, the subject-matter of Example 8 may optionally further include classifying each of the plurality of memory elements into a plurality of different correctability states based on results of the applying the error detection code and/or the error correction code.

In Example 10, the subject-matter of Example 6, 7, or 9 may optionally further include determining, from a result of the classifying, a present and/or future reliability of the memory device, and/or determining a further usability time span of operation without uncorrectable errors.

In Example 11, the subject-matter of any of Examples 1 to 10 may optionally include that an amount of the first offset current is identical to an amount of the second offset current, or that an amount of the first offset current is different from an amount of the second offset current.

In Example 12, the method of any of Examples 1 to 11 may further include that the memory device includes at least one detector electrically conductively connectable to the plurality of memory elements, an offset current source/drain electrically conductively connectable to the at least one detector, and a processor, and wherein the method is carried out using the memory device, optionally using the at least one detector for the margin read, using the offset current source/drain for applying the first offset current and/or the second offset current, and/or using the processor for the comparing and the determining the integrity state.

In Example 13, the subject-matter of Example 12 may optionally include that the at least one detector includes or consists of at least one sense amplifier.

In Example 14, the subject-matter of Example 12 or 13 may optionally include the plurality of memory elements and the at least one detector are electrically conductively connectable via at least one wordline.

In Example 15, the subject-matter of any of Examples 12 to 14 may optionally further include at least one switch, optionally a transistor or transmission gate, configured to switch the electrically conductive connection between a respective memory element of the plurality of memory elements and the at least one detector.

In Example 16, the subject-matter of any of Examples 12 to 15 may optionally further include at least one further switch, optionally a transistor or transimission gate, configured to switch the electrically conductive connection between the offset current source/drain and the at least one detector.

In Example 17, the subject-matter of any of Examples 12 to 16 may optionally include that the offset current source/drain is configured as a current source and configured, during any single margin read process, to provide an additive offset current, or that the offset current source/drain is configured as a current drain and configured, during any single margin read process to provide a subtractive offset current.

In Example 18, the subject-matter of any of Examples 12 to 17 may optionally further include the plurality of memory elements include or consist of resistive memory elements or charge trapping memory elements.

In Example 19, the subject-matter of any of Examples 12 to 18 may optionally further include that the plurality of memory elements are selected from the group consisting of: Resistive Random Access Memory, Magnetoresistive Random Access Memory, Phase-Change Random Access Memory, Ferroelectric Random Access Memory, floating gate flash memory, and charge trap flash memory.

Example 20 is a memory device. The memory device includes a plurality of memory elements, including: a first set of memory elements defined by a first bit value, and a second set of memory elements defined by a second bit value, at least one detector electrically conductively connectable to the plurality of memory elements, an offset current source/drain electrically conductively connectable to the at least one detector, and a processor, wherein the memory device is configured to carry out a margin read, including: reading the first set of memory elements applying a first offset current and comparing a sum formed by a current through the memory element and the first offset current with a first predefined reference current and with a second predefined reference current and/or reading the second set of memory elements applying a second offset current and comparing a sum formed by a current through the memory element and the second offset current with the first predefined reference current and with the second predefined reference current, determining the integrity state of the plurality of memory elements using the results of the reading the first set of memory elements and/or the second set of memory elements.

In Example 21, the subject-matter of Example 20 may optionally include that the at least one detector includes or consists of at least one sense amplifier.

In Example 22, the subject-matter of Example 20 or 21 may optionally include the plurality of memory elements and the at least one detector are electrically conductively connectable via at least one wordline.

In Example 23, the subject-matter of any of Examples 20 to 22 may optionally further include at least one switch, optionally a transistor, configured to switch the electrically conductive connection between a respective memory element of the plurality of memory elements and the at least one detector.

In Example 24, the subject-matter of any of Examples 20 to 23 may optionally further include at least one further switch, optionally a transistor, configured to switch the electrically conductive connection between the offset current source/drain and the at least one detector.

In Example 25, the subject-matter of any of Examples 20 to 24 may optionally include that the offset current source/drain is configured as a current source and configured, during any single margin read process, to provide an additive offset current, or that the offset current source/drain is configured as a current drain and configured, during any single margin read process to provide a subtractive offset current.

In Example 26, the subject-matter of any of Examples 20 to 25 may optionally further include the plurality of memory elements include or consist of resistive memory elements or charge trapping memory elements.

In Example 27, the subject-matter of any of Examples 20 to 26 may optionally further include that the plurality of memory elements are selected from the group consisting of: Resistive Random Access Memory, Magnetoresistive Random Access Memory, Phase-Change Random Access Memory, Ferroelectric Random Access Memory, floating gate flash memory, and charge trap flash memory.

In Example 28, the subject-matter of any of Examples 20 to 27 may optionally further be configured to carry out an initial read process, including: defining the memory elements for which a current through the cell during the read is lower than the first predefined reference current and lower than the second predefined reference current as belonging to the first set, defining the memory elements for which the current through the cell during the read is higher than the first predefined reference current and higher than the second predefined reference current as belonging to the second set, and defining the memory elements for which the current through the cell during the read is higher than the first predefined reference current and lower than the second predefined reference current as being in an unreliable state, applying an initial error correction to a result of the initial read process, and defining the memory elements that, after the initial error correction, are assigned the first bit value, as belonging to the first set, and defining the memory elements that, after the initial error correction, are assigned the second bit value, as belonging to the second set.

In Example 29, the subject-matter of Example 28 may optionally include that the defining the first set and the second set includes providing a predefined memory state pattern including first bit values that define the first set, and second bit values that define the second set.

In Example 30, the subject-matter of any of Examples 20 to 29 may optionally include that an offset direction of the second offset current is opposite to an offset direction of the first offset current.

In Example 31, the subject-matter of any of Examples 20 to 30 may optionally further include that the memory device is configured to provide the first offset current with a first direction and the second offset current with a second direction, wherein the sum formed by a current through the memory element and the first offset current is higher than the current through the memory element, and wherein the sum formed by a current through the memory element and the second offset current is lower than the current through the memory element, or that the sum formed by a current through the memory element and the first offset current is lower than the current through the memory element, and wherein the sum formed by a current through the memory element and the second offset current is higher than the current through the memory element.

In Example 32, the subject-matter of any of Examples 20 to 31 may optionally include that, for each memory element of the first set, a result of the comparing the sum formed by the current through the memory element and the first offset current with the first predefined reference current is a first read result, a result of the comparing the sum formed by the current through the memory element and the first offset current with the second predefined reference current is a second read result, the determining the integrity state including: classifying each of the memory elements of the first set into one of a plurality of correctability states, the classifying including: assigning a valid state to each memory element of the first set where the first read result and the second read result have the first bit value, assigning an unreliable state to each memory element of the first set where only one of the first read result and the second read result has the first bit value, and assigning a corrupt state to each memory element of the first set where none of the first read result and the second read result have the first bit value.

In Example 33, the subject-matter of any of Examples 20 to 32 may optionally include that, for each memory element of the second set, a result of the comparing the sum formed by the current through the memory element and the second offset current with the first predefined reference current is a third read result, a result of the comparing the sum formed by the current through the memory element and the second offset current with the second predefined reference current is a fourth read result, the determining the integrity state including: classifying each of the memory elements of the second set into one of a plurality of correctability states, the classifying including: assigning a valid state to each memory element of the second set where the third read result and the fourth read result have the second bit value, assigning an unreliable state to each memory element of the second set where only one of the third read result and the fourth read result has the second bit value, and assigning a corrupt state to each memory element of the second set where none of the third read result and the fourth read result have the second bit value.

In Example 34, the subject-matter of any of Examples 20 to 33 may optionally include that the carrying out the margin read includes the reading the first set of memory elements and the reading the second set of memory elements, and that the determining the integrity state of the plurality of memory elements includes applying an error detection code, EDC, and/or an error correction code, ECC, using the results of the reading the first set of memory elements and the second set of memory elements.

In Example 35, the subject-matter of Example 34 may optionally further include that the processor is configured to classify each of the plurality of memory elements into a plurality of different correctability states based on results of the applying the error detection code and/or the error correction code.

In Example 36, the subject-matter of Example 32, 33, or 35 may optionally further include that the processor is configured to determine, from a result of the classifying, a present and/or future reliability of the memory device, and/or determining a further usability time span of operation without uncorrectable errors.

In Example 37, the subject-matter of any of Examples 20 to 36 may optionally include that an amount of the first offset current is identical to an amount of the second offset current, or that an amount of the first offset current is different from an amount of the second offset current.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of determining an integrity state of a memory device, the memory device comprising a plurality of memory elements, comprising a first set of memory elements defined by a first bit value and a second set of memory elements defined by a second bit value, the method comprising:
performing a margin read, the margin read comprising:
reading the first set of memory elements applying a first offset current and comparing a sum formed by a current through the memory element and the first offset current with a first predefined reference current and with a second predefined reference current or reading the second set of memory elements applying a second offset current and comparing a sum formed by a current through the memory element and the second offset current with the first predefined reference current and with the second predefined reference current; and
determining the integrity state of the plurality of memory elements based on the results of the reading the first set of memory elements or the second set of memory elements.

2. The method of claim 1, further comprising:
performing an initial read process before the margin read process, the initial read process comprising:
defining the memory elements for which a current through a cell during the initial read process is lower than the first predefined reference current and lower than the second predefined reference current as belonging to the first set,
defining the memory elements for which the current through the cell during the initial read process is higher than the first predefined reference current and higher than the second predefined reference current as belonging to the second set,
defining the memory elements for which the current through the cell during the initial read process is higher than the first predefined reference current and lower than the second predefined reference current as being in an unreliable state;
applying an initial error correction to a result of the initial read process, and
defining the memory elements that, after the initial error correction, are assigned the first bit value, as belonging to the first set; and
defining the memory elements that, after the initial error correction, are assigned the second bit value, as belonging to the second set.

3. The method of claim 1,
wherein the defining the first set and the second set comprises providing a predefined memory state pattern comprising first bit values that define the first set, and second bit values that define the second set.

4. The method of claim 1,
wherein an offset direction of the second offset current is opposite to an offset direction of the first offset current.

5. The method of claim 1, comprising
providing the first offset current with a first direction and the second offset current with a second direction,
wherein the sum formed by a current through the memory element and the first offset current is higher than the current through the memory element, and wherein the sum formed by a current through the memory element and the second offset current is lower than the current through the memory element; or
wherein the sum formed by a current through the memory element and the first offset current is lower than the current through the memory element, and wherein the sum formed by a current through the memory element and the second offset current is higher than the current through the memory element.

6. The method of claim 1,
wherein, for each memory element of the first set, a result of the comparing the sum formed by the current through the memory element and the first offset current with the first predefined reference current is a first read result, a result of the comparing the sum formed by the current through the memory element and the first offset current with the second predefined reference current is a second read result; the determining the integrity state comprising:
classifying each of the memory elements of the first set into one of a plurality of correctability states, the classifying comprising:
assigning a valid state to each memory element of the first set when the first read result and the second read result have the first bit value;
assigning an unreliable state to each memory element of the first set when only one of the first read result and the second read result has the first bit value; and
assigning a corrupt state to each memory element of the first set when neither the first read result or the second read result have the first bit value.

7. The method of claim 1,
wherein, for each memory element of the second set, a result of the comparing the sum formed by the current through the memory element and the second offset current with the first predefined reference current is a third read result, a result of the comparing the sum formed by the current through the memory element and the second offset current with the second predefined reference current is a fourth read result; the determining the integrity state comprising:
classifying each of the memory elements of the second set into one of a plurality of correctability states, the classifying comprising:
assigning a valid state to each memory element of the second set when the third read result and the fourth read result have the second bit value;
assigning an unreliable state to each memory element of the second set when only one of the third read result and the fourth read result has the second bit value; and
assigning a corrupt state to each memory element of the second set when none of the third read result and the fourth read result have the second bit value.

8. The method of claim 1,
wherein the performing of the margin read comprises the reading the first set of memory elements and the reading the second set of memory elements; and
wherein the determining of the integrity state of the plurality of memory elements comprises applying an error detection code, EDC, and/or an error correction code, ECC, using the results of the reading the first set of memory elements and the second set of memory elements.

9. The method of claim 8, further comprising:
classifying each of the plurality of memory elements into a plurality of different correctability states based on results of the applying the error detection code or the error correction code.

10. The method of claim 1, further comprising:
determining, from a result of the determining of the integrity state, a present or future reliability of the memory device, and/or
determining a further usability time span of operation without uncorrectable errors.

11. The method of claim 1,
wherein an amount of the first offset current is identical to an amount of the second offset current; or
wherein an amount of the first offset current is different from an amount of the second offset current.

12. A memory device, comprising:
a plurality of memory elements, comprising:
a first set of memory elements defined by a first bit value; and
a second set of memory elements defined by a second bit value;
at least one detector electrically conductively connectable to the plurality of memory elements;
an offset current source or drain electrically conductively connectable to the at least one detector, and
a processor;
wherein the memory device is configured to carry out a margin read, comprising:
reading the first set of memory elements applying a first offset current and comparing a sum formed by a current through the memory element and the first offset current with a first predefined reference current and with a second predefined reference current or reading the second set of memory elements applying a second offset current and comparing a sum formed by a current through the memory element and the second offset current with the first predefined reference current and with the second predefined reference current;
determining the integrity state of the plurality of memory elements using the results of the reading the first set of memory elements and/or the second set of memory elements.

13. The memory device of claim 12, wherein the at least one detector comprises at least one sense amplifier.

14. The memory device of claim 12, wherein the plurality of memory elements and the at least one detector are electrically conductively connectable via at least one wordline.

15. The memory device of claim 12, further comprising a transistor or transmission gate, configured to switch the electrically conductive connection between a respective memory element of the plurality of memory elements and the at least one detector.

16. The memory device of claim 12, further comprising at least one further transistor or transmission gate, configured to switch the electrically conductive connection between the offset current source or drain and the at least one detector.

17. The memory device of claim 12,
wherein the offset current source or drain is configured as a current source that is configured to, during any single margin read process, provide an additive offset current, or
wherein the offset current source or drain is configured as a current drain and configured, during any single margin read process to provide a subtractive offset current.

18. The memory device of claim 12, wherein the plurality of memory elements comprise resistive memory elements or charge trapping memory elements.

19. The memory device of any of claim 12, wherein the plurality of memory elements are selected from the group consisting of:
Resistive Random Access Memory;
Magnetoresistive Random Access Memory;
Phase-Change Random Access Memory;
Ferroelectric Random Access Memory;
floating gate flash memory; and
charge trap flash memory.
